(19) United States
(12) Patent Application Publication
(10) Pub. No.: US 2026/0085234 A1
(43) Pub. Date: Mar. 26, 2026

(54) t-DABNA-BASED THERMALLY ACTIVATED DELAYED FLUORESCENT (TADF) MOLECULES FOR BLUE OLED DEVICE

(71) Applicant: SAMSUNG DISPLAY CO., LTD., Yongin-si (KR)

(72) Inventors: Cheol Woo Park, San Jose, CA (US); Shuhui Qu, Santa Clara, CA (US)

(21) Appl. No.: 19/196,658

(22) Filed: May 1, 2025

Related U.S. Application Data
(60) Provisional application No. 63/642,563, filed on May 3, 2024.

(51) Int. Cl. C09K 11/06; H10K 50/11; H10K 85/60; H10K 101/10; H10K 101/30

(52) U.S. Cl. CPC C09K 11/06; H10K 50/11; H10K 85/658; C09K 2211/1014; H10K 2101/10; H10K 2101/30

(57) ABSTRACT

An organic molecule is disclosed for improving the display properties of OLED devices. The organic molecule may include a structure represented by Formula 1, and the structure is modified by suitable fragments which may result in similar occupied spaces in HOMO and LUMO, thereby resulting in a lower energy level of the singlet excited state S1, a lower energy level of HOMO, and a reduced energy difference between the singlet excited state S1 and the triplet excited state T1 of the organic molecule. An OLED device including the organic molecule shows improved quality, high efficiency, and long-life characteristics.

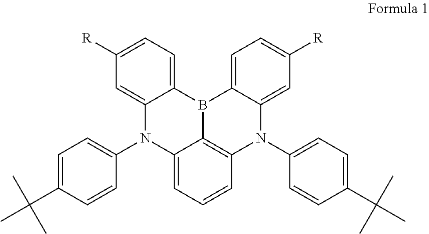

### CROSS-REFERENCE TO RELATED APPLICATION

The present application claims priority to and the benefit of Provisional U.S. Patent Application No. 63/642,563, filed in the United States Intellectual Property Office on May 3, 2024, the entire disclosure of which is incorporated herein by reference.

### BACKGROUND

### 1. Field

Aspects of some embodiments relate to an organic molecule applied in an Organic Light-Emitting Diode (OLED) device. For example, aspects of some embodiments of the present disclosure relate to improvements to a blue OLED emitter in the OLED device.

### 2. Description of the Related Art

Recently, OLEDs have become the core technology in display devices; however, due to the demands for longer lifespan and better display quality of OLED devices, a development of organic molecules for a light-emitting element capable of stably attaining such characteristics is being consistently pursued.

The above information disclosed in this Background section is only for enhancement of understanding of the background, and therefore the information discussed in this Background section does not necessarily constitute prior art.

### SUMMARY

Aspects according to one or more embodiments of the present disclosure are directed toward an organic molecule showing improved molecular properties to be applied in a light-emitting element.

Aspects according to one or more embodiments of the present disclosure are directed toward a light-emitting element including an organic molecule with improved molecular properties, which shows an improved purity of color and long-life characteristics.

Aspects according to one or more embodiments of the present disclosure are directed toward an electronic device applying an organic molecule with improved molecular properties, which shows high efficiency and long-life characteristics.

Additional aspects will be set forth in part in the description which follows

and, in part, will be apparent from the description, or may be learned by practice of the presented embodiments of the disclosure.

According to a first embodiment of the present disclosure, an organic molecule may include a structure represented by Formula 1:

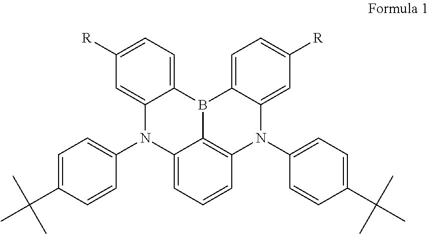

wherein R is selected from a group consisting of:

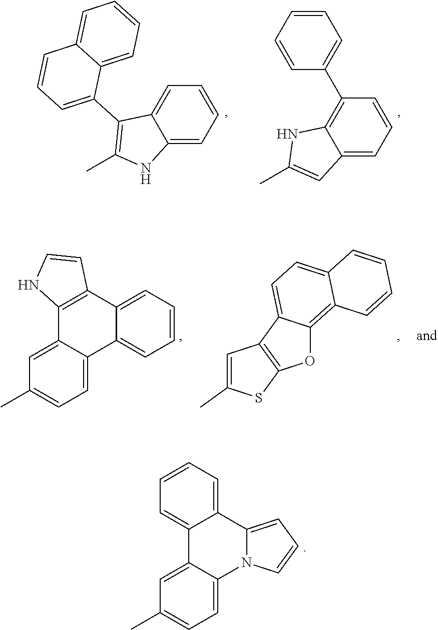 [SMILES: Cc1[nH]c2ccccc2c1-c1cccc2ccccc12 ; Cc1cc2cccc(-c3ccccc3)c2[nH]1 ; Cc1ccc2c3ccccc3c3cc[nH]c3c2c1 ; Cc1cc2c(oc3c4ccccc4ccc23)s1 ; Cc1ccc2c(c1)c1ccccc1c1cccn12]

In one or more embodiments, the organic molecule may be a modified t-DABNA-based TADF molecule.

In one or more embodiments, the organic molecule may be applied to a blue Organic Light-Emitting Diode (OLED) emitter.

In one or more embodiments, an energy level of the organic molecule in a singlet excited state S1 may be lower than about 3 eV.

In one or more embodiments, an energy level of the organic molecule in a Highest Occupied Molecular Orbital (HOMO) may be lower than about-5 eV.

In one or more embodiments, an energy difference (ΔE_{ST}) of the organic molecule between a singlet excited state S1 and a triplet excited state T1 may be lower than or equal to about 0.40 eV.

In one or more embodiments, an Oscillator Strength (OSC) of the organic molecule may be greater than or equal to about 0.36 eV.

According to a second embodiment of the present disclosure, a light-emitting element may include a first electrode, a second electrode on the first electrode, and an emission layer between the first electrode and the second electrode and including an organic molecule including a structure of Formula 1 shown in the first embodiment of the present disclosure.

In one or more embodiments, the light-emitting element may include a blue OLED emitter.

According to a third embodiment of the present disclosure, an electronic device may include a light-emitting element including a first electrode, a second electrode on the first electrode, and an emission layer between the first electrode and the second electrode and including an organic molecule including a structure of Formula 1 as shown in the first embodiment of the present disclosure.

In one or more embodiments, the electronic device may include a mobile phone, a smartphone, a tablet personal computer (PC), a mobile communication terminal, an electronic organizer, an electronic book, a portable multimedia player (PMP), a navigation system, a navigation device, an ultra-mobile PC (UMPC), a television, a laptop, a monitor, an electric vehicle, a billboard, an Internet of Things (IoT) device, a smartwatch, a watch phone, and/or a head-mounted display (HMD).

In one or more embodiments, the electronic device may include a blue OLED emitter including the organic molecule.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The above and other aspects of the present disclosure will be more clearly understood from the following detailed description of the illustrative, non-limiting embodiments with reference to the accompanying drawings.

FIG. 1 is a block diagram of an organic light-emitting display device according to one or more embodiments of the present disclosure.

FIG. 2 is a circuit diagram of a pixel according to one or more embodiments of the present disclosure.

FIG. 3 is a plan view showing a display apparatus according to one or more embodiments of the present disclosure.

FIG. 4 is a schematic cross-sectional view illustrating light-emitting devices according to one or more embodiments of the present disclosure.

FIG. 5A is a diagram depicting an example formation of excitons.

FIG. 5B is a diagram depicting a molecule in a singlet ground state, a singlet excited state, and a triplet excited state, respectively.

FIG. 6A is a diagram depicting an example approach utilized in the first generation of OLEDs.

FIG. 6B is a diagram depicting an example approach utilized in the second generation of OLEDs.

FIG. 6C is a diagram depicting an example approach utilized in the third generation of OLEDs.

FIG. 7A illustrates example molecular structures of a TADF molecule, PXZ-TRZ.

FIG. 7B is a diagram depicting example spatial distributions in HOMO and LUMO of another TADF molecule, DMAC-TRZ.

FIG. 7C illustrates diagrams depicting an example stokes shift caused by a spatial difference in molecular structures.

FIG. 8 is a diagram depicting an example hot exciton in OLEDs.

FIG. 9 is a diagram depicting an example pipeline to engineer the moieties of t-DABNA-based TADF molecule, according to one or more embodiments of the present disclosure.

FIG. 10A is a diagram depicting designed t-DABNA-based TADF molecules, according to one or more embodiments of the present disclosure.

FIG. 10B is a diagram depicting the occupied space of the designed t-DABNA-based TADF molecules in LUMO and HOMO, according to one or more embodiments of the present disclosure.

FIG. 11 is a flowchart depicting an example method for designing t-DABNA-based TADF molecules, according to one or more embodiments of the present disclosure.

FIG. 12 is a schematic diagram of an electronic device according to one or more embodiments of the present disclosure.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the terms “or” and “and/or” include any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on-a-chip (SoC), an assembly, and so forth.

The electronic or electric devices and/or any other relevant devices or components according to embodiments of the present disclosure described herein may be implemented utilizing any suitable hardware, firmware (e.g., an application-specific integrated circuit (ASIC)), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

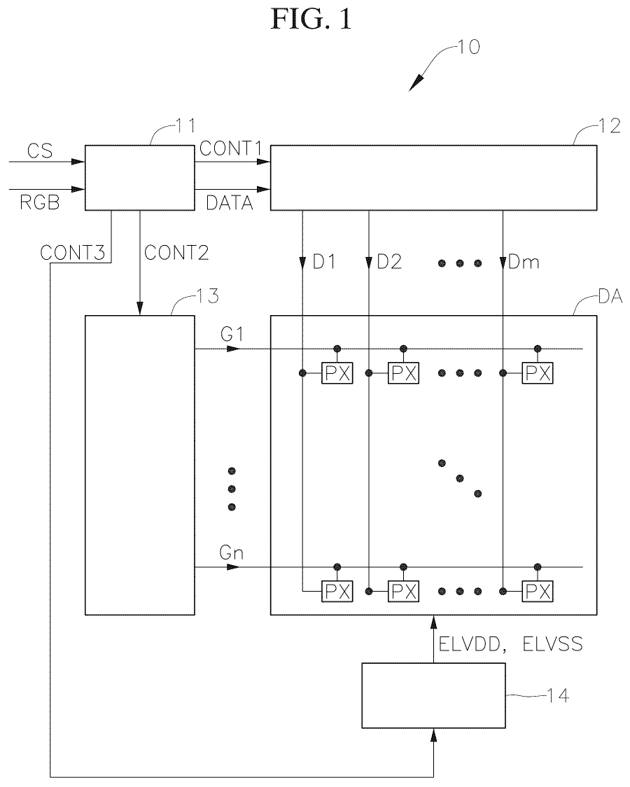

FIG. 1 is a block diagram of an organic light-emitting display device according to one or more embodiments of the present disclosure.

Referring to FIG. 1, an organic light-emitting display device 10 includes a display area DA, a signal controller 11, a data driver 12, a scan driver 13, a gate driver, and a power supply 14.

The display area DA may be an area where images are displayed. The display area DA according to an embodiment of the present disclosure is shown in FIG. 1 as having a rectangular shape for illustrating a circuit connection. However, an actual shape of the display area will be described in further detail later. The display area DA may include a plurality of gate lines, a plurality of data lines intersecting with the plurality of gate lines, and a plurality of pixels PX each connected to the respective gate lines and data lines. The plurality of data lines may be extended in a row direction (e.g., a direction in which the number of rows increments). The plurality of gate lines may be extended in a column direction (e.g., a direction in which the number of columns increments). A plurality of power supply lines may be further disposed in the display area DA. Each of the plurality of power supply lines may be connected to the respective pixels PX.

The signal controller 11 may receive a control signal CS and image signals R, G, and B from an external device. The image signals R, G, and B contain luminance information of the plurality of pixels PX. In some embodiments, the control signal CS may include a vertical synchronization signal (Vsync), a horizontal synchronization signal (Hsync), a data enable signal (DE), and a clock signal (CLK). The signal controller 11 may generate first to third driving control signals CONT1 to CONT3 and image data DATA according to the image signals R, G, and B and the control signal CS.

The gate driver may be connected to the plurality of gate lines in the display area DA and may generate a plurality of gate signals G1 to Gn according to the second driving control signal CONT2. The gate driver 140 may sequentially apply the plurality of gate signals G1 to Gn at a gate-on voltage level to the plurality of gate lines.

The data driver 12 may be connected to the plurality of data lines in the display area DA, and may sample and hold the image data DATA input in response to the first driving control signal CONT1 to convert it into an analog voltage, thereby generating a plurality of data signals D1 to Dm. The data driver 12 may transmit the plurality of data signals D1 to Dm to the respective data lines. The pixels PX in the display area DA may be turned on individually upon receiving the gate signals G1 to Gn at the gate-on voltage level and may receive the data signals D1 to Dm.

The scan driver 13 may be connected to the plurality of gate lines in the display area DA and may generate the plurality of scan signals G1 to Gn in response to the second driving control signal CONT2, to provide them to the gate lines.

The power supply 14 may supply a first supply voltage ELVDD and a second supply voltage ELVSS to a plurality of power supply lines connected to the plurality of pixels PX. The first supply voltage ELVDD and the second supply voltage ELVSS may generate a driving current for each of the pixels PX.

In some embodiments, the gate signals G1 to Gn, the data signals D1 to Dm, the first supply voltage ELVDD, the second supply voltage ELVSS and other signals may be provided to each of the pixels via additional lines. In some embodiments, these signals may be used for initializing certain nodes, compensating threshold voltages, and detecting and compensating degradation, to improve the display quality the organic light-emitting display device 10.

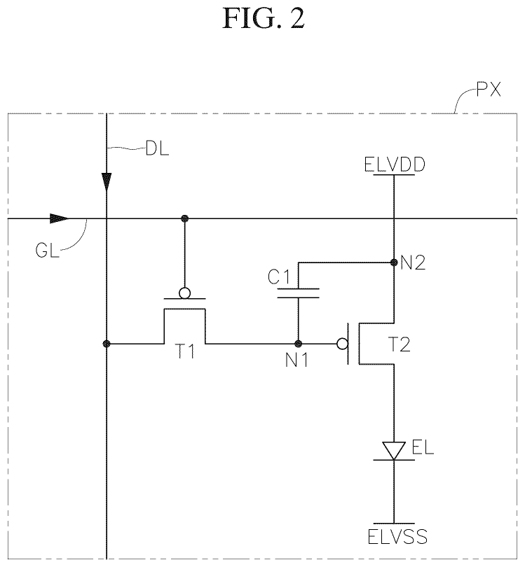

FIG. 2 is a circuit diagram of an example pixel according to one or more embodiments of the present disclosure. Although FIG. 2 illustrates various components in a pixel according to some embodiments, embodiments according to the present disclosure are not limited thereto, and according to various embodiments, the pixel may include additional components or fewer components without departing from the spirit and scope of embodiments according to the present disclosure.

Referring to FIG. 2, a pixel PX includes a first transistor T1, a second transistor T2, a first capacitor C1, and an organic light-emitting element EL.

The first transistor T1 may include a control electrode connected to a gate line GL, an input electrode connected to a data line DL, and an output electrode connected to a first node N1. The first transistor T1 may be turned on upon receiving a gate signal having the voltage level of the on-level applied to the gate line GL, and may transmit a data signal to the first node N1.

The second transistor T2 may include a control electrode connected to the first node N1, an input electrode connected to a second node N2, and an output electrode connected to an anode electrode of the organic light-emitting element EL. The second node N2 may receive the first supply voltage ELVDD.

The first capacitor C1 may be disposed between the first node N1 and the second node N2. The data signal provided from the first transistor T1 may charge the first capacitor C1 with the corresponding voltage. The first capacitor C1 may hold the voltage at the control electrode of the second transistor T2 to a predetermined level. The second transistor T2 may control the driving current supplied from the first supply voltage ELVDD to the organic light-emitting element EL based on the voltage held at the first node N1.

The organic light-emitting element EL may include an anode electrode connected to a third node, a cathode electrode connected to the second supply voltage ELVSS, and an organic emission layer. The organic emission layer may emit light of one of primary colors. In some embodiments, the primary colors may be the three colors of red, green, and blue. A desired color may be displayed by combining these three primary colors in the same space or at the same time. The organic emission layer may include a small-molecule organic material or a polymer organic material corresponding to each color. Depending on the amount of current flowing through the organic emission layer, the organic material corresponding to each color can emit light. For example, the organic material may include a thermally activated delayed fluorescence (TADF) molecule which is applied in a blue light-emitting element.

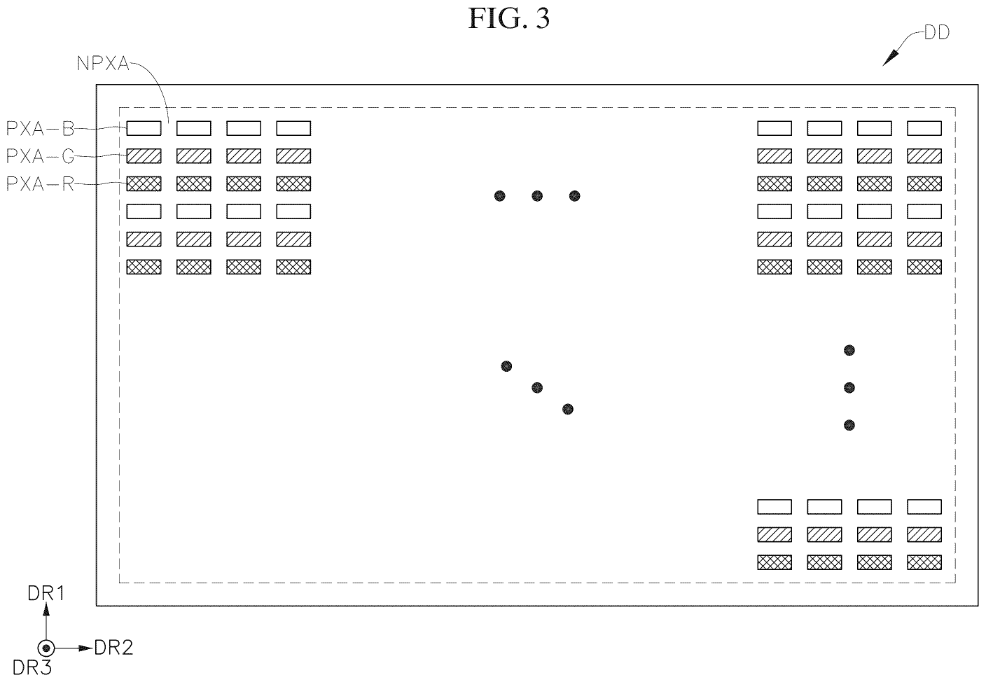

FIG. 3 is a plan view showing a display apparatus according to one or more embodiments of the present disclosure.

The display apparatus DD (e.g., corresponding to the display device 10 of FIG. 1) may include a display panel and an optical layer located on the display panel. The display apparatus DD may include multiple light-emitting elements. The optical layer may be located on the display panel and control reflection of external light at the display panel. The optical layer may include, for example, a polarization layer and/or a color filter layer.

Referring to FIG. 3, the display apparatus DD may include a non-luminous (e.g., non-light-emitting) area NPXA and luminous (e.g., light-emitting) areas PXA-R, PXA-G and PXA-B. The luminous areas PXA-R, PXA-G and PXA-B may be areas emitting light produced from the light-emitting elements, respectively. The luminous areas PXA-R, PXA-G and PXA-B may be separated from each other on a plane (e.g., in a plan view).

The luminous areas PXA-R, PXA-G and PXA-B may be divided into multiple groups according to the color of light produced from the light-emitting elements. In the display apparatus DD of an embodiment, shown in FIG. 3, three luminous areas PXA-R, PXA-G and PXA-B emitting red light, green light, and blue light, respectively, are illustrated as an embodiment. For example, the display apparatus DD of an embodiment may include a red luminous area PXA-R, a green luminous area PXA-G and a blue luminous area PXA-B, which are separated from each other.

In the display apparatus DD according to an embodiment, multiple light-emitting elements may be to emit light having different wavelength regions. For example, the display apparatus DD may include a first light-emitting element emitting red light, a second light-emitting element emitting green light, and a third light-emitting element emitting blue light. For example, each of the red luminous area PXA-R, the green luminous area PXA-G, and the blue luminous area PXA-B of the display apparatus DD may correspond to the first light-emitting element, the second light-emitting element, and the third light-emitting element, respectively.

However, one or more embodiments of the present disclosure are not limited thereto, and the first to third light-emitting elements may be to emit light in the same (or substantially the same) wavelength region, or at least one thereof may be to emit light in a different wavelength region. For example, the first to third light-emitting elements may all emit blue light.

The luminous areas PXA-R, PXA-G and PXA-B in the display apparatus DD according to one or more embodiments may be arranged in a stripe shape. Referring to FIG. 3, multiple red luminous areas PXA-R may be arranged with each other along a second directional axis DR2, multiple green luminous areas PXA-G may be arranged with each other along the second directional axis DR2, and multiple blue luminous areas PXA-B may be arranged with each other along the second directional axis DR2. In some embodiments, the red luminous area PXA-R, the green luminous area PXA-G and the blue luminous area PXA-B may be alternately arranged in this stated order along a first directional axis DR1.

In FIG. 3, the areas of the luminous areas PXA-R, PXA-G and PXA-B are shown as similar in size, but one or more embodiments of the present disclosure are not limited thereto. The areas of the luminous areas PXA-R, PXA-G and PXA-B may be different from each other according to the wavelength region of light emitted. In some embodiments, the areas of the luminous areas PXA-R, PXA-G and PXA-B may refer to areas when viewed on a plane defined by the first directional axis DR1 and the second directional axis DR2 (e.g., in a plan view).

In some embodiments, the arrangement of the luminous areas PXA-R, PXA-G and PXA-B is not limited to the configuration shown in FIG. 3, and the arrangement order of the red luminous areas PXA-R, the green luminous areas PXA-G and the blue luminous areas PXA-B may be provided in one or more suitable combinations according to the properties of display quality required or desired for the display apparatus DD.

In some embodiments, the areas of the luminous areas PXA-R, PXA-G and PXA-B may be different from each other. For example, the area of the green luminous area PXA-G may be smaller than the area of the blue luminous area PXA-B, but one or more embodiments of the present disclosure are not limited thereto.

In some embodiments, the first to third light-emitting elements ED-1, ED-2 and ED-3, may include an organic molecule (e.g., the TADF molecule), which will be explained in more detail.

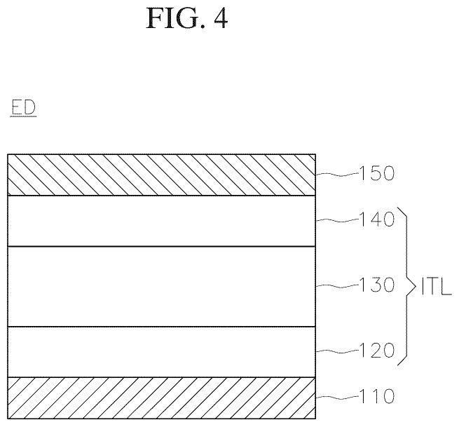

FIG. 4 is a schematic cross-sectional view illustrating light-emitting devices according to one or more embodiments of the present disclosure.

Referring to FIG. 4, a light-emitting device ED may include a first electrode 110, a second electrode 150, and an intermediate layer ITL interposed between the first electrode 110 and the second electrode 150. The intermediate layer ITL may include an emission layer 130. The intermediate layer ITL may further include a hole transfer region 120 and an electron transfer region 140.

The first electrode 110 may be an anode or a cathode. In one or more embodiments, the first electrode 110 may be an anode, and may serve as a pixel electrode. In this case, the first electrode 110 may include a conductive material with a high work function that promotes hole injection.

In one or more embodiments, the first electrode 110 may be a transmissive electrode. The first electrode 110 may include a transparent conductive oxide such as indium tin oxide (ITO), indium zinc oxide (IZO), zinc oxide (ZnO), indium tin oxide (ITZO), and/or the like.

In one or more embodiments, the first electrode 110 may be a translucent electrode or a reflective electrode. The first electrode 110 may include at least one of Ag, Mg, Cu, Al, Pt, Pd, Au, Ni, Nd, Ir, Cr, Li, Ca, LiF, Mo, Ti, W, In, Sn, Zn, and an alloy containing at least two therefrom. For example, the first electrode 110 may include Li, Ca, LiF/Ca (e.g., a stacked structure of LiF and Ca), LiF/AI (e.g., a stacked structure of LiF and Al), a mixture of Ag and Mg, and/or the like.

The first electrode 110 may have a single-layered structure or a multi-layered structure. For example, the first electrode 110 may have a triple-layered structure of ITO/Ag/ITO.

A thickness of the first electrode 110 may be in a range of about 700 Å to about 10,000 Å. For example, the thickness of the first electrode 110 may be in a range of about 1,000 Å to about 3,000 Å.

The second electrode 150 may be a cathode or an anode. In one or more embodiments, the second electrode 150 may serve as an electron injection electrode or as a cathode. The second electrode 150 may include a metal, an alloy, an electrically conductive compound, and/or the like, having a low work function.

For example, the second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, and/or the like. The second electrode 150 may include one of the aforementioned materials, and/or a (e.g., any suitable) combination thereof.

The second electrode 150 may be a transmissive electrode, a translucent electrode, or a reflective electrode. The second electrode 150 may have a single-layered structure or a multi-layered structure.

The emission layer 130 may include a condensed heterocyclic compound. In one or more embodiments, the condensed heterocyclic compound may serve as a fluorescent dopant. For example, the condensed heterocyclic compound may serve as a TADF dopant.

The hole transfer region 120 may be formed between the first electrode 110 and the emission layer 130. The hole transfer region 120 may have a single-layered or a multi-layered region including different materials.

The hole transfer region 120 may include a hole injection layer, a hole transport layer, and/or an electron blocking layer, and may further include an auxiliary emission layer.

The electron transfer region 140 between the second electrode 150 and the emission layer 130. The electron transfer region 140 may have a single-layered, or a multi-layered structure region including different materials.

The electron transfer region 140 may include an electron injection layer, an electron transport layer, and/or a hole blocking layer, and may further include an auxiliary emission layer.

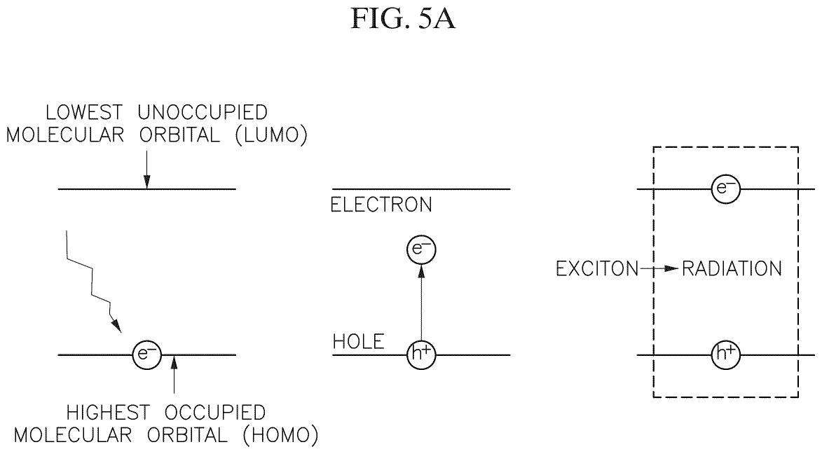

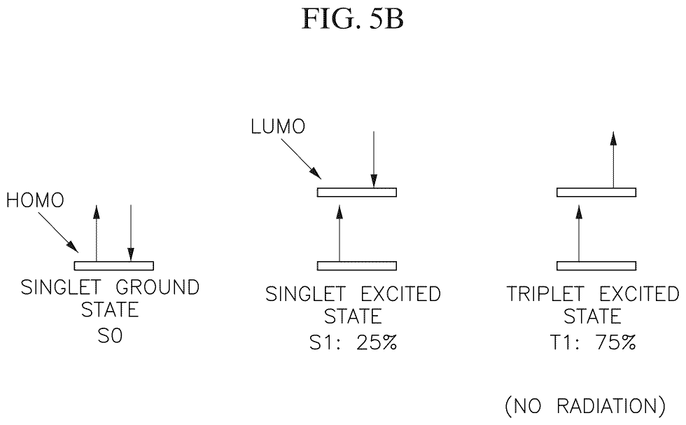

FIG. 5A is a diagram depicting an example formation of excitons. FIG. 5B is a diagram depicting a molecule in a singlet ground state, a singlet excited state, and a triplet excited state, respectively.

Organic Light Emitting Diodes (OLEDs) have been developed over decades and have become the main technology behind the current commercial displays. In the current commercial displays, OLEDs emit light through excitons (e.g., an electron-hole pair). For example, referring FIG. 5A, when an electron is excited from Highest Occupied Molecular Orbital (HOMO) to Lowest Unoccupied Molecular Orbital (LUMO) (e.g., the electron is excited into a higher energy state via absorption of a photon and/or another excitation method, such as voltages), the excited electron may create a positively charged hole in HOMO (e.g., the lower energy level), which results in the formation of the exciton, e.g., the electron-hole pair. When the electron is relaxed from LUMO (e.g., the higher energy state) back to HOMO (e.g., the lower energy state or the ground state), the electrons emit light, which is the light emitted from the OLED displays. For example, if (e.g., when) the exciton is not stable (e.g., not in a stable state), the electron and hole eventually recombine, releasing the energy the electron-hole pair held in the form of a photon (light/radiation).

Referring to FIG. 5B, one of the principles in quantum mechanics is the Pauli exclusion principle, in which each molecular orbital may house up to two electrons. If (e.g., when) these two electrons exist in a molecular orbital, they may have opposite spins (e.g., the electrons spin in opposite directions). On the contrary, if (e.g., when) they have the same spin (e.g., the electrons spin in the same direction), they may be excited together because spinning in the same direction does not conserve the angular momentum. For example, if (e.g., when) these electrons are excited, there may be a 25% chance that the electrons are left behind in HOMO (e.g., the electrons have the opposite spins), and a 75% chance that the electrons are excited to LUMO because the electrons have the same spins. In this case, the state of the electrons having the opposite spins is called a singlet state, e.g., including a singlet ground state S0 and a singlet excited state S1. The state of the electrons having the same spins is called a triplet state, e.g., triplet excited state T1.

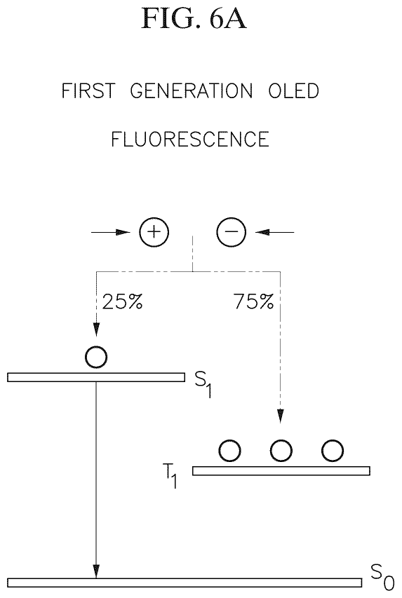

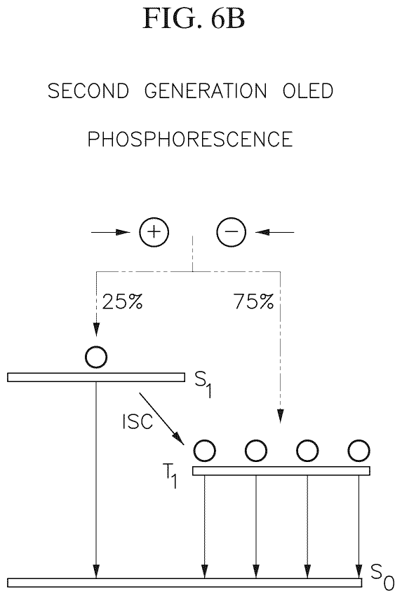

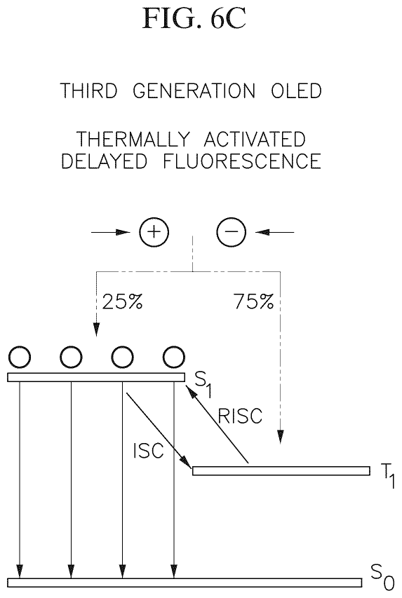

FIG. 6A is a diagram depicting an example approach utilized in the first generation of OLEDs. FIG. 6B is a diagram depicting an example approach utilized in the second generation of OLEDs. FIG. 6C is a diagram depicting an example approach utilized in the third generation of OLEDs.

Referring to FIG. 6A, for those excitons in the triplet excited state T1, the electrons may not be relaxed back to the singlet ground state S0 (e.g., HOMO) because the electrons spin in the same direction, such that the electrons spinning in the same direction may not emit light. Therefore, the efficiency of the first-generation OLEDs (e.g., a fluorescence OLED/a flexible OLED) is about 25% because only 25% of the electrons (e.g., the electrons spinning in the opposite directions or in the singlet excited state S1) may fall back to the singlet ground state S0 to emit light, and about 75% of the electrons (e.g., the electrons spinning in the same direction or in the triplet excited state T1) may not return back to the singlet ground state S0.

Referring to FIG. 6B, for the electrons spinning in the same direction (e.g., the electrons in the triplet excited state T1) to return back to the singlet ground state S0 to increase the efficiency of the first-generation OLEDs, a phosphorescent OLED is developed in the second-generation OLEDs by applying heavy metal elements, e.g., Iridium (Ir) and/or Platinum (Pt), in the TADF molecules. Because the heavy metal elements in the TADF molecules may promote spin-orbit coupling (SOC) between the singlet excited state S1 and the triplet excited state T1, it may causes Intersystem Crossing (ISC) to allow a molecule to transit from the singlet excited state S1 to the triplet excited state T1, such that the electrons in the triplet excited state T1 may be back to the singlet ground state S0 to emit light. The efficiency and brightness of the second-generation OLEDs may be improved (e.g., to achieve about 100% of efficiency). However, the heavy metal elements, e.g., Iridium (Ir) and Platinum (Pt), utilized in the second-generation OLEDs are expensive.

Referring FIG. 6C, TADF molecules are utilized in the third-generation OLEDs. If (e.g., when) the TADF molecules are applied, the difference of the energy level between the singlet excited state S1 and the triplet excited state T1 may be reduced to a minimum or a relatively small/little difference. Therefore, the TADF molecules may be transited from the triplet excited state T1 to the singlet excited state S1 through Reverse Intersystem Crossing (RISC), such that the electrons that are transformed to the singlet excited state S1 may be relaxed to the singlet ground state S0 to emit light. The advantages of utilizing the TADF molecules in OLEDs are higher efficiency (e.g., about 100%) and lower cost. However, in terms of applying blue TADF molecules to the OLEDs, improving efficiency, achieving industry-grade color purity, and extending the lifetime of blue OLED emitter may still be needed.

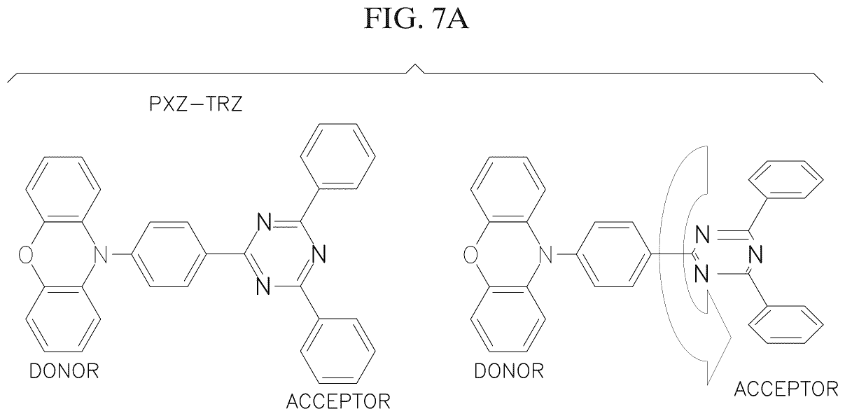

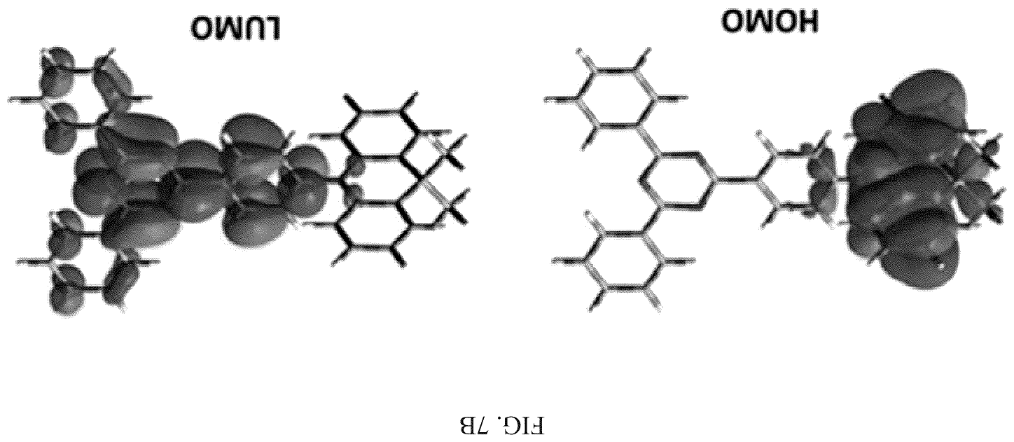

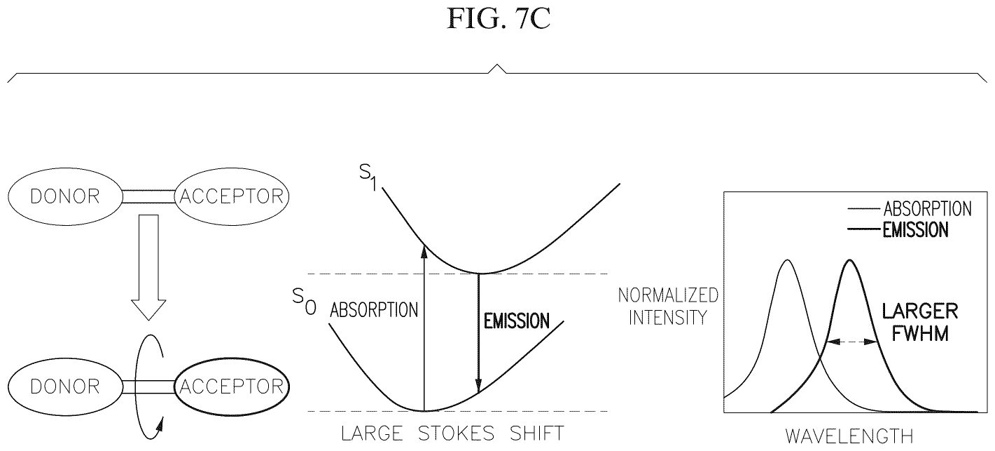

FIG. 7A illustrates example molecular structures of a TADF molecule, PXZ-TRZ. FIG. 7B is a diagram depicting example spatial distributions of HOMO and LUMO of another TADF molecule, DMAC-TRZ. FIG. 7C illustrates diagrams depicting an example stokes shift caused by the spatial difference in molecular structures.

Referring to FIG. 7A, a TADF molecule is generally designed through a donor-acceptor architecture which includes an electron-donating (donor) unit and an electron-accepting (acceptor) unit. Such a donor-acceptor architecture may render a large stokes shift which further causes low color purity. For example, PXZ-TRZ shown in FIG. 7A has a bipolar structure with phenoxazine (PXZ) as an electron-donating unit/fragment/moiety and 2,4,6-triphenyl-1,3,5-triazine (TRZ) as an electron-accepting unit/fragment/moiety. If (e.g., when) PXZ-TRZ is excited from HOMO to LUMO, the single bond between PXZ (e.g., an electron donor) and TRZ (e.g., an electron acceptor) may function as a pivot point to rotate TRZ which causes the spatial difference between two states (e.g., the singlet ground state S0 and the singlet excited state S1). Such a spatial difference may contribute to minimizing the energy gap (e.g., the difference of the energy level between the singlet excited state S1 and the triplet excited state T1 discussed in FIG. 6C) to improve the efficiency of OLEDs. However, when the rotation happens during the excitation (e.g., to LUMO) and the relaxation/emission (e.g., to HOMO), a significant shift or change in the geometry of its molecular structure may happen.

Molecular structures of a TADF molecule, DMAC-TRZ, in HOMO and LUMO are illustrated in FIG. 7B. DMAC-TRZ has a bipolar structure with 9,9-dimethyl-9,10-dihydroacridine (DMAC) as the electron-donating unit and TRZ as the electron-accepting unit. A difference of occupied space (structurally) between the excited DMAC-TRZ (e.g., DMAC-TRZ in LUMO) and the relaxed DMAC-TRZ (e.g., DMAC-TRZ in HOMO) may be observed as shown in FIG. 7B. For example, the bonding (e.g., the single bond) between the fragment of DMAC and the fragment of TRZ is rotated during the excitation or the emission, the structural space of DMAC-TRZ in HOMO is different from the structural space of DMAC-TRZ in LUMO.

Referring to FIG. 7C, because of such a difference in structural space, the singlet ground state S0 and the singlet excited state S1 may be shifted or changed based on the geometry. For example, based on the nature of quantum mechanics, an electron or a molecule would try to stay in the valley of the singlet ground state S0 (e.g., the lowest point of the singlet ground state S0). When the molecule gets excited, the excited molecule may not be in the valley of the singlet excited state S1 (e.g., the lowest point of the singlet excited state S1) because of the shift or the change in the energy landscape of each state. Likewise, when the molecule gets relaxed, the relaxed molecule may return to a new or different valley of the singlet ground state S0 which might not be the lowest point of the singlet ground state S0. Because the rotation happens during the excitation or the relaxation, it may cause a stokes shift in the energy (e.g., absorption energy and/or emission energy) due to the geometry change in molecular structures, which may further render a wider wavelength of the absorption/emission spectrum. Such a wide emission spectrum would directly affect the purity of color, because the larger the full width of half maximum (FWHM) of the emission spectrum is, the worse the purity of color is. For example, a wider emission spectrum or larger FWHM indicates that the emission energies may vary in a wide range which results in emitting lights in different colors.

To address the above issues caused by the spatial difference between the molecular structures in HOMO and LUMO, it is beneficial and ideal to minimize such a spatial difference in molecular structures between HOMO and LUMO. Therefore, Multi-Resonance (MR) type TADF molecules have been studied and are shown to overcome the issue of large FWHM by having a rigid core structure that has a minimal structural change during the excitation (e.g., in LUMO) and/or the emission (e.g., in HOMO). Such a MR type TADF molecule is shown to have similar occupied space structurally in LUMO and in HOMO, so that the stokes shift is smaller because of the minimized spatial difference, and furthermore, the FWHM is smaller to improve the purity of color. However, these MR-type TADF molecules usually have long or relatively longer exciton lifetime, which may cause degradation and short lifespan in OLEDs. For example, because the MR-type TADF molecule has a relatively rigid structure (e.g., a core with minimum change structurally), an exciton does not have enough space/freedom to relax back to the ground state (e.g., a lower energy state), which might cause degradation in OLEDs.

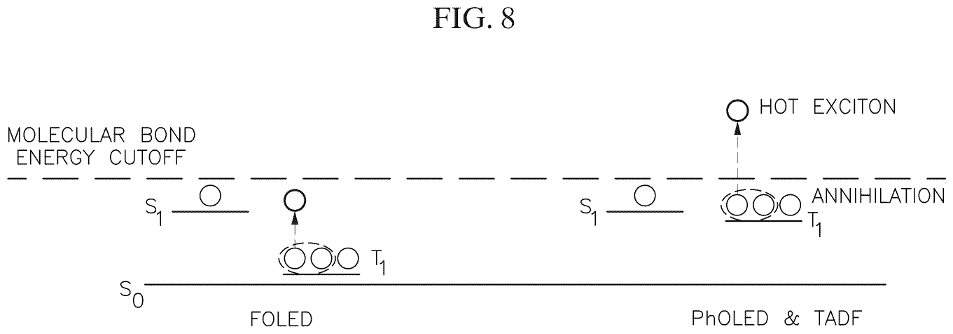

FIG. 8 is a diagram depicting an example hot exciton in OLEDs.

If (e.g., when) some of the excitons in the triplet excited state T1 do not go back to the singlet ground state S0 to emit light, exciton annihilation may happen, which refers to that two or more adjacent excitons may collide with one another to reach a higher energy level, or one exciton may absorb the energy from the adjacent excitons to reach to a higher energy level while the adjacent excitons return to the ground state (e.g., a level having zero energy). An exciton having a higher energy due to the exciton annihilation is called a hot exciton. A hot exciton having energy greater than a molecular bond energy cutoff is able to break a molecular bond in a molecule, which causes degradation in OLEDs.

Referring FIG. 8, a hot exciton in Flexible OLED (FOLED) (e.g., the first-generation OLED) usually does not have an energy that is greater than the molecular bond energy cutoff because its triplet excited state T1 has a lower energy level. On the other hand, a hot exciton in Phosphorescent OLED (PhOLED) (e.g., the second-generation OLED) and TADF-based OLED (e.g., the third-generation OLED) may readily have energy that is greater than the molecular bond energy cutoff, which may cause degradation and short lifespan in OLEDs.

To overcome the above issues (e.g., the hot exciton) to improve the lifespan of the OLEDs, there are some molecular properties to consider, including: (1) a deeper HOMO (e.g., a ground state with a lower energy level); (2) a smaller energy gap between the singlet excited state S1 and the triplet excited state T1 (ΔE_{ST}); and (3) a stronger oscillator strength (OSC) for the transition from the singlet ground state (S0) to the singlet excited state S1. One or more moieties of a MR-type TADF emitter, a t-DABNA-based TADF molecule, may be engineered to achieve the above molecular properties.

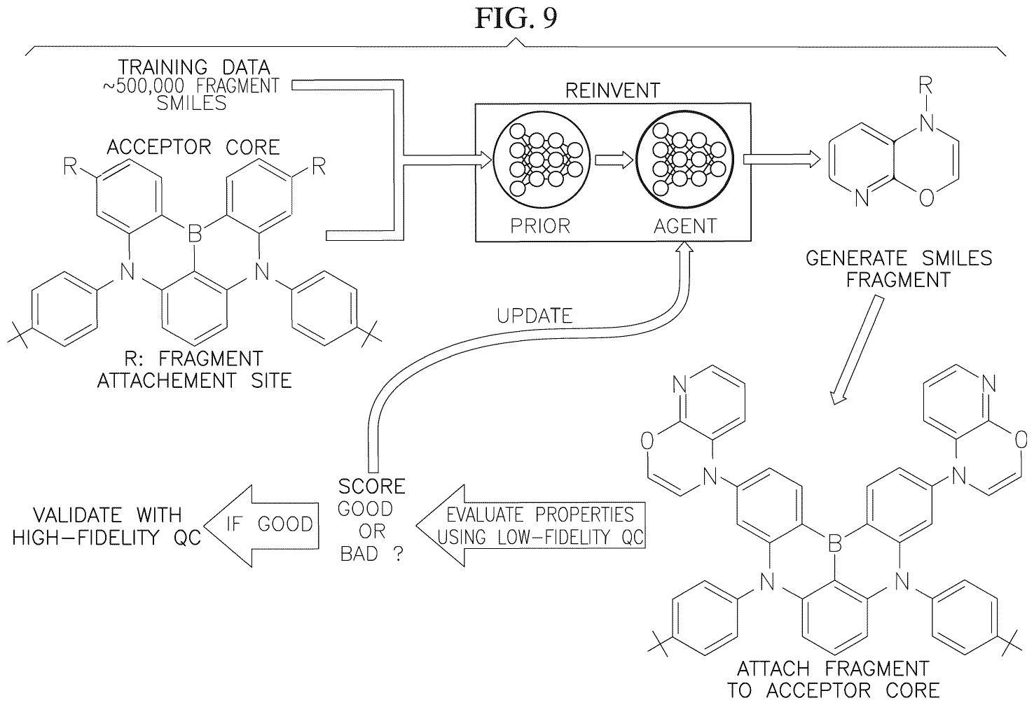

FIG. 9 is a diagram depicting an example pipeline to engineer the moieties of the t-DABNA-based TADF molecule, according to one or more embodiments of the present disclosure.

For moiety engineering the MR-type TADF emitter to achieve the above molecular properties (e.g., a deeper HOMO, a smaller ΔE_{ST}, and/or a greater OSC), a machine learning model for engineering the t-DABNA-based TADF molecule may be built. Referring to FIG. 9, a pipeline to build the machine learning model for engineering the t-DABNA-based TADF molecule is shown. An acceptor core of the t-DABNA-based TADF molecule is selected as a basic structure and a part of training data. The acceptor core may have a structure represented by Formula 1.

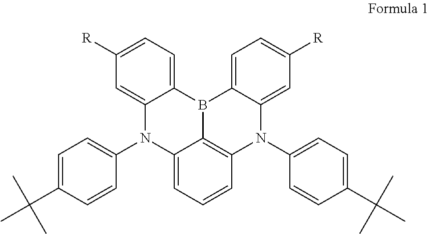

In Formula 1, R may be a binding site for a potential fragment (e.g., a fragment attachment site, a fragment, a functional group, and/or a substitute). Therefore, the training data may further include over 500,000 fragments based on Simplified Molecular-Input Line-Entry System (SMILES) to generate or design suitable fragments for modifying the t-DABNA-based TADF molecule.

Once suitable fragments are generated by teaching the machine learning model utilizing the training data, the machine learning model may output potential t-DABNA-based TADF molecules by attaching generated fragments to the acceptor core.

Furthermore, the output t-DABNA-based TADF molecules may be evaluated to determine their molecular properties (e.g., an energy level of HOMO, AEST, and an OSC) utilizing low-fidelity Quantum Chemistry (QC) simulation. Each of the output t-DABNA-based TADF molecules is scored based on the evaluation. For example, if (e.g., when) an OSC of an output t-DABNA-based TADF molecule is higher than the OSC of the t-DABNA-based TADF molecule without designed fragments, a higher score will be assigned to indicate a better/strong candidacy of the output t-DABNA-based TADF molecule. The scored t-DABNA-based TADF molecules may be fed back to the machine learning model as updated training data to improve the quality and accuracy of the output. For example, the output t-DABNA-based TADF molecules with higher scores may be utilized to update the machine learning model to improve the quality and accuracy of outputting designed t-DABNA-based TADF molecules, which may achieve the designed or desired molecular properties. In some embodiments, semiempirical and ab initio quantum simulation tools may also be applied in evaluating the molecular properties of the output t-DABNA-based TADF molecules, e.g., an electronic structure.

The output t-DABNA-based TADF molecules with higher scores may be further validated utilizing high-fidelity QC simulation. In some embodiments, a language model may be utilized to train fragments from SMILES. For example, benzene may be encoded as c1ccccc1.

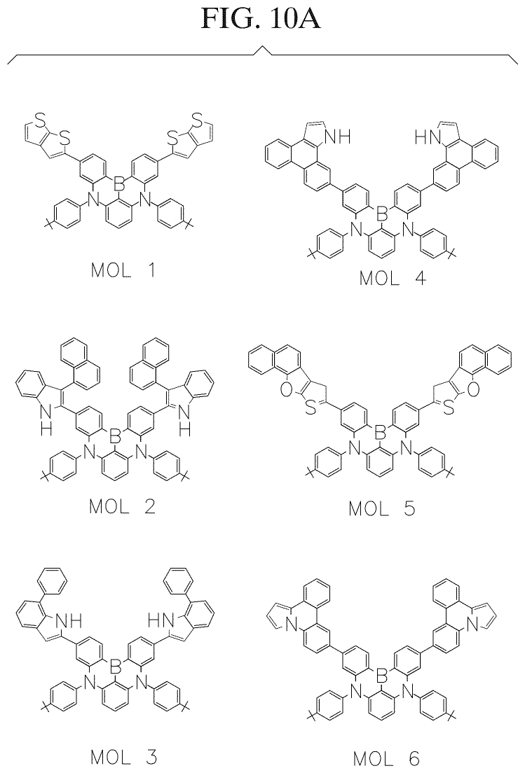

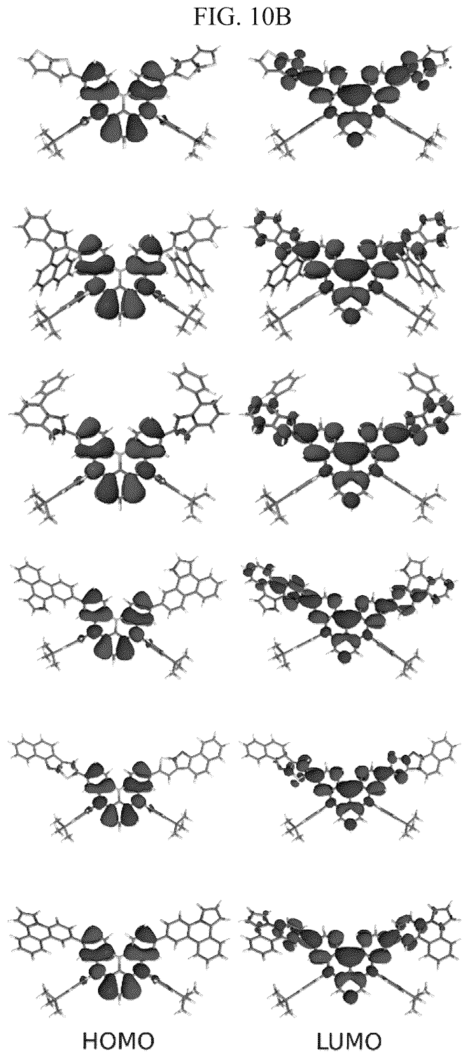

FIG. 10A is a diagram depicting designed t-DABNA-based TADF molecules, according to one or more embodiments of the present disclosure. FIG. 10B is a diagram depicting the occupied space of the designed t-DABNA-based TADF molecules in LUMO and HOMO, according to one or more embodiments of the present disclosure.

Referring to FIG. 10A, the designed t-DABNA-based TADF molecules may include Mol1, Mol2, Mol3, Mol4, Mol5, and Mol6 represented by Formula 1-1 to Formula 1-6, respectively.

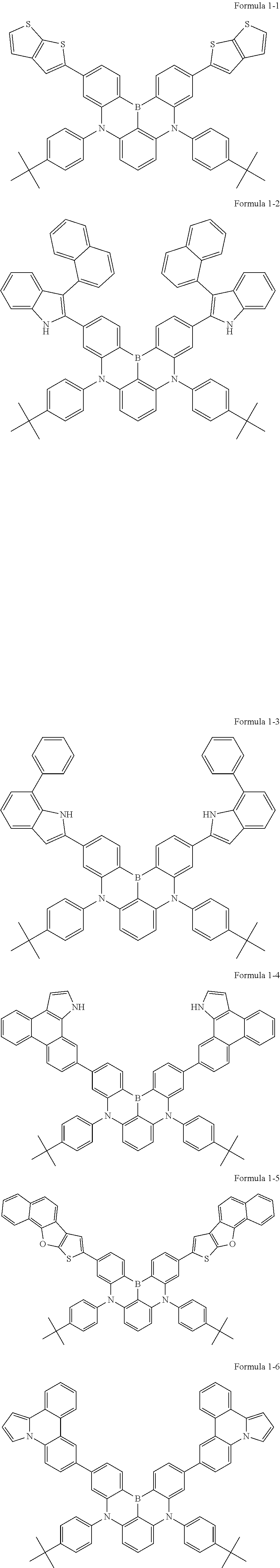

Referring to FIG. 10B, the structural differences of Mol1, Mol2, Mol3, Mol4, Mol5, and Mol6 between HOMO and LUMO are relatively minimal. For example, the occupied structural space of Mol1 in HOMO is substantially the same as the occupied structural space of Mol1 in LUMO.

Furthermore, the molecular properties of t-DABNA, Mol1, Mol2, Mol3, Mol4, Mol5, and Mol6 are measured utilizing density functional theory, where the exchange correlation may be B3LYP, and the basis function may be 6-311++G (d,p).

In Table 1, the energy level of the singlet excited state S1, the energy level of HOMO, ΔE_{ST}, and the OSC of t-DABNA, Mol1, Mol2, Mol3, Mol4, Mol5, and Mol6 measured are shown.

TABLE 1

| | | | | Oscillator |
|---|---|---|---|---|
| | S₁ | HOMO | ΔE_{ST} | Strength |
| Molecule | (eV) | (eV) | (eV) | (OSC) |
| t-DABNA | 3.02 | −4.84 | 0.47 | 0.225 |
| Mol1 | 2.81 | −5.05 | 0.40 | 0.363 |
| Mol2 | 2.84 | −5.06 | 0.40 | 0.365 |
| Mol3 | 2.82 | −5.07 | 0.40 | 0.411 |
| Mol4 | 2.84 | −5.05 | 0.38 | 0.410 |
| Mol5 | 2.80 | −5.08 | 0.39 | 0.484 |
| Mol6 | 2.88 | −5.05 | 0.39 | 0.418 |

As shown in Table 1, Mol1 to Mol6 show a lower energy level of the singlet excited state S1 than t-DABNA, which may improve the transition from the singlet excited state S1 to the triplet excited state T1 to emit light and reduce the risk of rendering a hot exciton. Furthermore, Mol1 to Mol6 show a deeper HOMO (e.g., a lower energy level of HOMO).

Mol1 to Mol6 further show a smaller ΔE_{ST} (e.g., an energy gap between the singlet excited state S1 and the triplet excited state T1), which may improve the transition from the singlet excited state S1 to the triplet excited state T1 to emit light, thereby extending the lifespan of OLEDs. Furthermore, Mol1 to Mol6 show a stronger OSC which may improve the transition from the singlet ground state S0 to the singlet excited state S1, thereby reducing the chance of generating a hot exciton.

According to one or more embodiments, the designed t-DABNA-based TADF molecules achieve improved molecular properties (e.g., a deeper HOMO, a smaller ΔE_{ST}, and a greater OSC), which may prolong the lifetime of the blue OLEDs and improve the efficiency of the blue OLEDs, that may be incorporated into OLED display panels, thereby improving the lifetime and quality (e.g., the purity of color) of the OLED display panels.

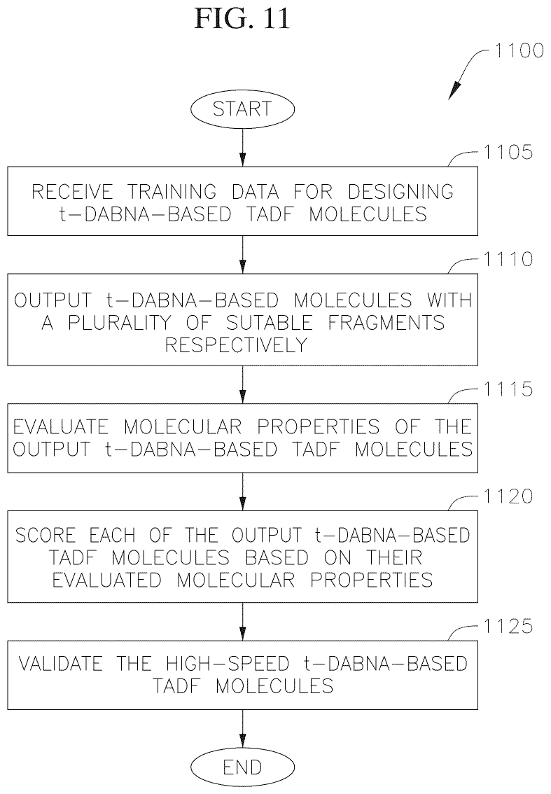

FIG. 11 is a flowchart depicting a method for designing t-DABNA-based TADF molecules, according to one or more embodiments of the present disclosure.

Although FIG. 11 illustrates various operations in a method for designing the t-DABNA-based TADF molecules, one or more embodiments according to the present disclosure are not limited thereto, and according to one or more embodiments, the method may include additional operations or fewer operations, or the order of operations may vary, unless otherwise stated or implied, without departing from the spirit and scope of embodiments according to the present disclosure.

Referring to FIG. 11, at operation 1105, a machine learning model receives training data for designing the t-DABNA-based TADF molecules. The training data may include an acceptor core and a plurality of fragments that may be attached to the acceptor core. In one or more embodiments, the acceptor core may have a structure represented by Formula 1.

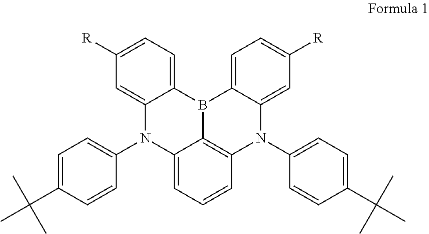

In one or more embodiments, the plurality of fragments may be selected from among:

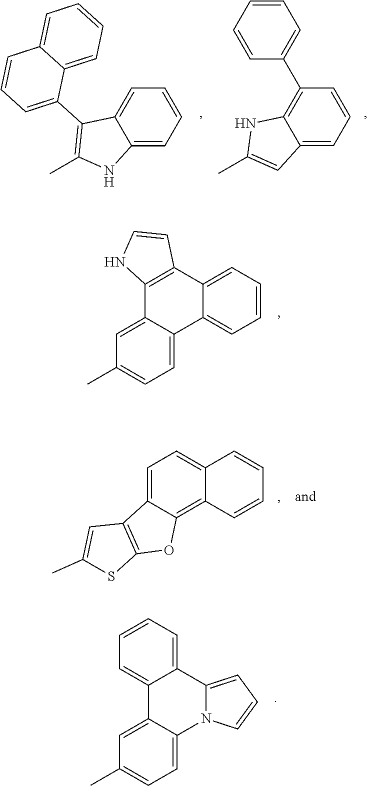 [SMILES: Cc1[nH]c2ccccc2c1-c1cccc2ccccc12 ; Cc1cc2cccc(-c3ccccc3)c2[nH]1 ; Cc1ccc2c3ccccc3c3cc[nH]c3c2c1 ; Cc1cc2c(oc3c4ccccc4ccc23)s1 ; Cc1ccc2c(c1)c1ccccc1c1cccn12]

At operation 1110, the machine learning model may output t-DABNA-based TADF molecules modified with a plurality of suitable fragments, respectively.

At operation 1115, the machine learning model may evaluate the molecular properties of the output t-DABNA-based TADF molecules. In one or more embodiments, the molecular properties may include an energy level of the singlet excited state S1, an energy level of HOMO, AEST, and an OSC of an output t-DABNA-based TADF molecule. In one or more embodiments, the molecular properties may be evaluated utilizing low-fidelity QC simulation.

At operation 1120, the machine learning model may score each of the output t-DABNA-based TADF molecules based on their evaluated molecular properties. In one or more embodiments, the machine learning model may be updated/re-trained with high-scored t-DABNA-based TADF molecules.

At operation 1125, the machine learning model may validate the high-scored t-DABNA-based TADF molecules.

In one or more embodiments, the high-scored t-DABNA-based TADF molecules may be validated utilizing high-fidelity QC simulation.

In one or more embodiments, the trained machine learning model may output a designed t-DABNA-based TADF molecule that satisfies the designed molecular properties. The designed t-DABNA-based TADF molecule may include a structure represented by any one of Formula 1-1 to Formula 1-6.

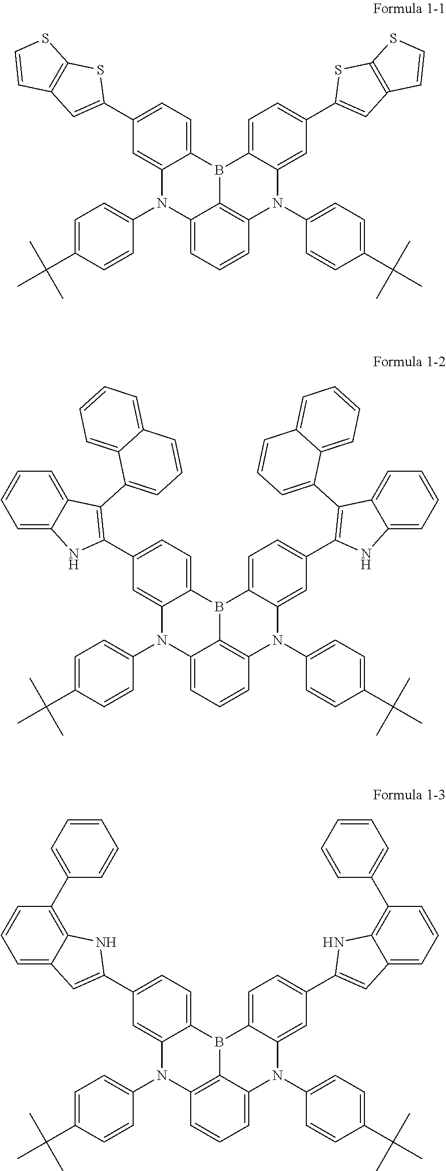 [SMILES: CC(C)(C)c1ccc(N2c3cc(-c4cc5ccsc5s4)ccc3B3c4ccc(-c5cc6ccsc6s5)cc4N(c4ccc(C(C)(C)C)cc4)c4cccc2c43)cc1 ; CC(C)(C)c1ccc(N2c3cc(-c4[nH]c5ccccc5c4-c4cccc5ccccc45)ccc3B3c4ccc(-c5[nH]c6ccccc6c5-c5cccc6ccccc56)cc4N(c4ccc(C(C)(C)C)cc4)c4cccc2c43)cc1 ; CC(C)(C)c1ccc(N2c3cc(-c4cc5cccc(-c6ccccc6)c5[nH]4)ccc3B3c4ccc(-c5cc6cccc(-c7ccccc7)c6[nH]5)cc4N(c4ccc(C(C)(C)C)cc4)c4cccc2c43)cc1]

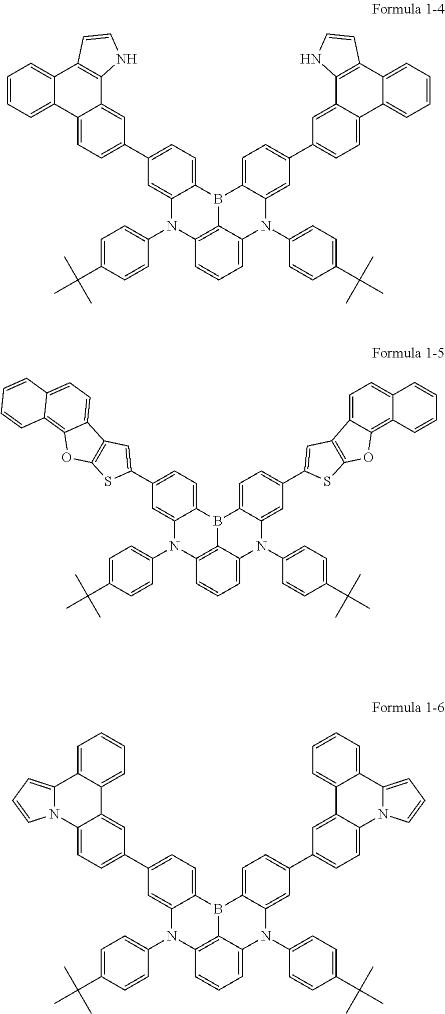 [SMILES: CC(C)(C)c1ccc(N2c3cc(-c4ccc5c6ccccc6c6cc[nH]c6c5c4)ccc3B3c4ccc(-c5ccc6c7ccccc7c7cc[nH]c7c6c5)cc4N(c4ccc(C(C)(C)C)cc4)c4cccc2c43)cc1 ; CC(C)(C)c1ccc(N2c3cc(-c4cc5c(oc6c7ccccc7ccc56)s4)ccc3B3c4ccc(-c5cc6c(oc7c8ccccc8ccc67)s5)cc4N(c4ccc(C(C)(C)C)cc4)c4cccc2c43)cc1 ; CC(C)(C)c1ccc(N2c3cc(-c4ccc5c(c4)c4ccccc4c4cccn45)ccc3B3c4ccc(-c5ccc6c(c5)c5ccccc5c5cccn56)cc4N(c4ccc(C(C)(C)C)cc4)c4cccc2c43)cc1]

In one or more embodiments, the designed t-DABNA-based TADF molecule may be applied to a blue OLED emitter.

In one or more embodiments, an energy level of the designed t-DABNA-based TADF molecule in a singlet excited state S1 may be lower than about 3 eV.

In one or more embodiments, an energy level of the designed t-DABNA-based TADF molecule in HOMO may be lower than about-5 eV.

In one or more embodiments, an energy difference (AEST) of the designed t-DABNA-based TADF molecule between the singlet excited state S1 and the triplet excited state T1 may be lower than or equal to about 0.40 eV.

In one or more embodiments, an OSC of the designed t-DABNA-based TADF molecule may be greater than or equal to about 0.36 eV.

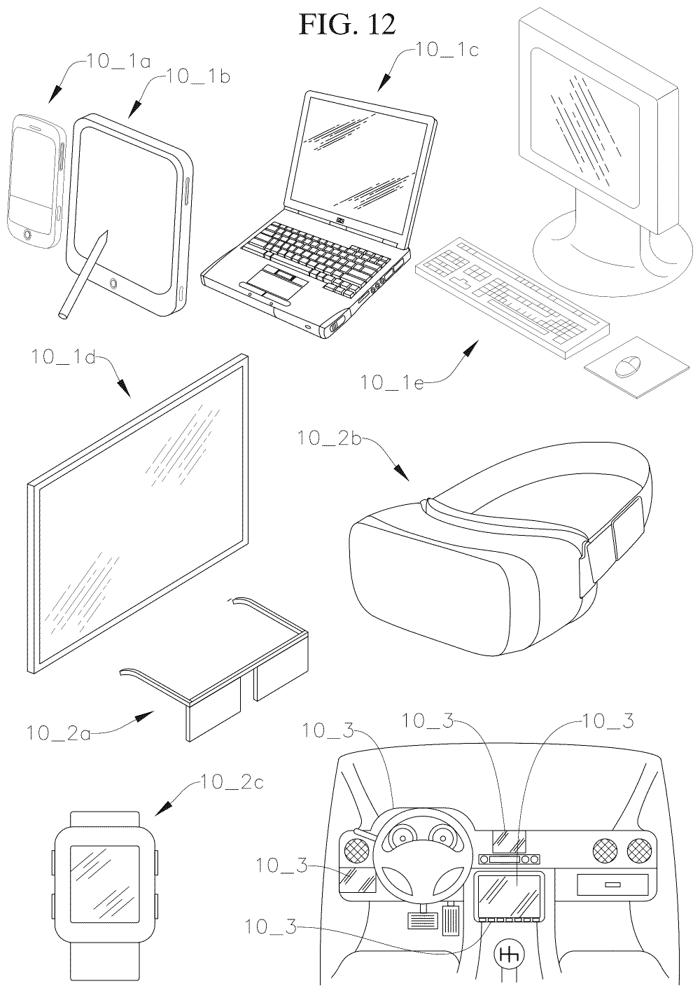

FIG. 12 is a schematic diagram of an electronic device according to one or more embodiments of the present disclosure.

Referring to FIG. 12, non-limiting examples of one or more suitable electronic devices to which the display device according to the above-described embodiments is applied include an electronic device for displaying an image such as a smartphone 10_1a, a tablet PC 10_1b, a laptop 10_1c, a TV 10_1d, a desk monitor 10_1e, and/or the like; a wearable electronic device including a display module such as smart glasses 10_2a, a head mounted display 10_2b, a smart watch 10_2c, and/or the like; a vehicle electronic device 10_3 including a display module such as a center information display (CID) arranged at a vehicle instrument panel, a center fascia, a dashboard, and/or the like, a room mirror display, and/or the like. The electronic device may include a virtual reality glass or an augmented reality glass.

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Alternatively or additionally, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations may be depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims, with functional equivalents thereof to be included therein.

What is claimed is:

1. An organic molecule, comprising a structure represented by Formula 1: 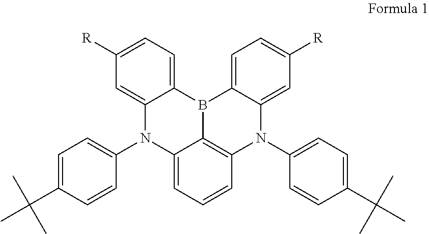
wherein R is selected from a group consisting of:

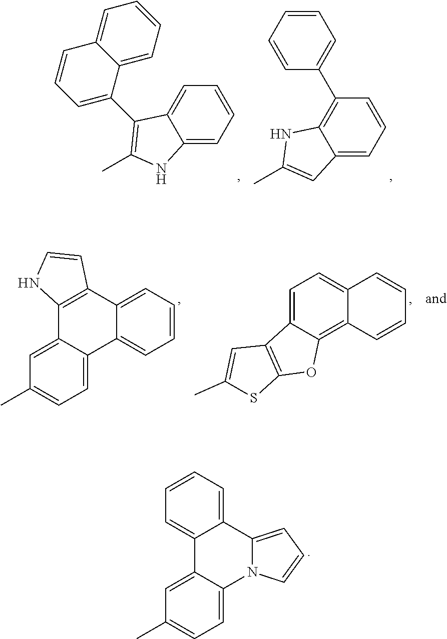 [SMILES: Cc1[nH]c2ccccc2c1-c1cccc2ccccc12 ; Cc1cc2cccc(-c3ccccc3)c2[nH]1 ; Cc1ccc2c3ccccc3c3cc[nH]c3c2c1 ; Cc1cc2c(oc3c4ccccc4ccc23)s1 ; Cc1ccc2c(c1)c1ccccc1c1cccn12]

2. The organic molecule of claim 1, wherein the organic molecule is a modified t-DABNA-based TADF molecule.

3. The organic molecule of claim 1, wherein the organic molecule is applied to a blue Organic Light-Emitting Diode (OLED) emitter.

4. The organic molecule of claim 1, wherein an energy level of the organic molecule in a singlet excited state S1 is lower than about 3 eV.

5. The organic molecule of claim 1, wherein an energy level of the organic molecule in Highest Occupied Molecular Orbital (HOMO) is lower than about-5 eV.

6. The organic molecule of claim 1, wherein an energy difference (ΔE_{ST}) of the organic molecule between a singlet excited state S1 and a triplet excited state T1 is lower than or equal to about 0.40 eV.

7. The organic molecule of claim 1, wherein an Oscillator Strength (OSC) of the organic molecule is greater than or equal to about 0.36 eV.

8. A light-emitting element comprising:
a first electrode;
a second electrode on the first electrode; and
an emission layer between the first electrode and the second electrode, and comprising an organic molecule comprising a structure of Formula 1: 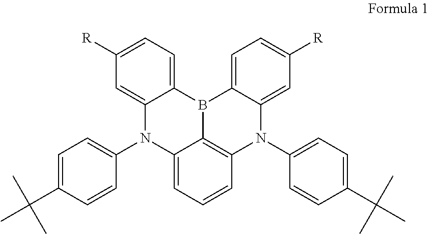
wherein R is selected from a group consisting of:

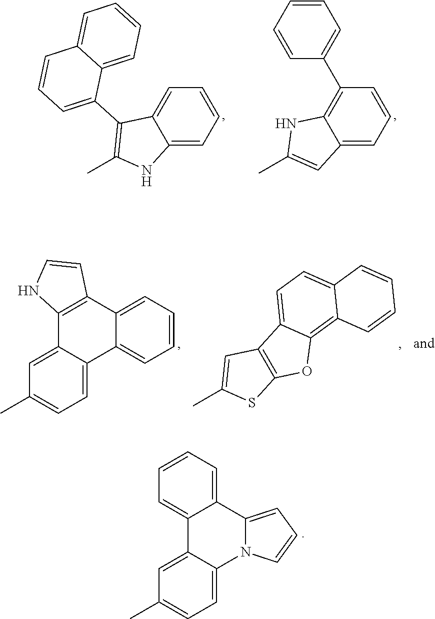

9. The light-emitting element of claim 8, wherein the light-emitting element includes a blue OLED emitter.

10. The light-emitting element of claim 8, wherein an energy level of the organic molecule in a singlet excited state S1 is lower than about 3 eV.

11. The light-emitting element of claim 8, wherein an energy level of the organic molecule in HOMO is lower than about −5 eV.

12. The light-emitting element of claim 8, wherein an energy difference (ΔE_{ST}) of the organic molecule between a singlet excited state S1 and a triplet excited state T1 is lower than or equal to about 0.40 eV.

13. The light-emitting element of claim 8, wherein an OSC of the organic molecule is greater than or equal to about 0.36 eV.

14. An electronic device comprising:
a light-emitting element comprising:
a first electrode;
a second electrode on the first electrode; and
an emission layer between the first electrode and the second electrode, and comprising an organic molecule comprising a structure of Formula 1: 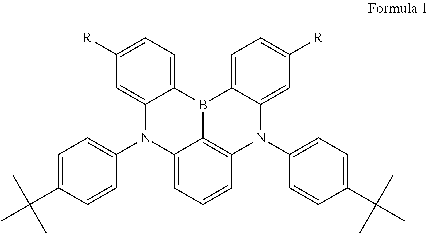
wherein R is selected from a group consisting of:

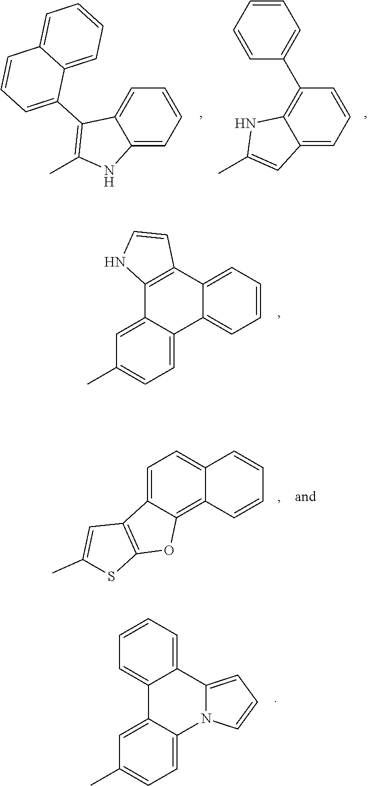 [SMILES: Cc1[nH]c2ccccc2c1-c1cccc2ccccc12 ; Cc1cc2cccc(-c3ccccc3)c2[nH]1 ; Cc1ccc2c3ccccc3c3cc[nH]c3c2c1 ; Cc1cc2c(oc3c4ccccc4ccc23)s1 ; Cc1ccc2c(c1)c1ccccc1c1cccn12]

15. The electronic device of claim 14, wherein the electronic device comprises a mobile phone, a smartphone, a tablet personal computer (PC), a mobile communication terminal, an electronic organizer, an electronic book, a portable multimedia player (PMP), a navigation system, a navigation device, an ultra-mobile PC (UMPC), a television, a laptop, a monitor, an electric vehicle, a billboard, an Internet of Things (IoT) device, a smartwatch, a watch phone, and/or a head-mounted display (HMD).

16. The electronic device of claim 14, wherein the electronic device comprises a blue OLED emitter comprising the organic molecule.

17. The electronic device of claim 14, wherein an energy level of the organic molecule in a singlet excited state S1 is lower than about 3 eV.

18. The electronic device of claim 14, wherein an energy level of the organic molecule in HOMO is about lower than about-5 eV.

19. The electronic device of claim 14, wherein an energy difference (ΔE_{ST}) of the organic molecule between a singlet excited state S1 and a triplet excited state T1 is lower than or equal to about 0.40 eV.

20. The electronic device of claim 14, wherein an OSC of the organic molecule is greater than or equal to about 0.36 eV.
